(19) United States
(12) Patent Application Publication
(10) Pub. No.: US 2007/0229707 A1
(43) Pub. Date: Oct. 4, 2007

(54) Apparatus and Method for Canceling Distortion

(75) Inventor: Mark Francis Rumreich, Indianapolis, IN (US)

Correspondence Address: JOSEPH J. LAKS, VICE PRESIDENT;THOMSON LICENSING LLC, PATENT OPERATIONS, PO BOX 5312, PRINCETON, NJ, 08543-5312, US

(73) Assignee: Thomson Licensing Inc., Princeton, NJ (US)

(21) Appl. No.: 11/596,443

(22) PCT Filed: May 11, 2005
(86) PCT No.: PCT/US05/16383

§ 371 Date: Nov. 14, 2006

Related U.S. Application Data
(60) Provisional application No. 60/572,998, filed on May 20, 2004.

(51) Int. Cl. H03M 1/12

(52) U.S. Cl. 348/573

(57) ABSTRACT

An apparatus such as a television signal receiver is capable of canceling non-linear distortion, such as second harmonic distortion in a picture carrier, when performing digital signal processing. According to an exemplary embodiment, the apparatus includes a digital signal source for providing a digital signal and a digital signal processor for digitally processing the digital signal to generate a digitally processed signal. The processor includes distortion canceling circuitry for canceling non-linear distortion from the digital signal

### CROSS REFERENCE TO RELATED APPLICATION

This application claims priority to and all benefits accruing from a provisional application filed in the United States Patent and Trademark Office on May 20, 2004, and having assigned Ser. No. 60/572,998.

### BACKGROUND OF THE INVENTION

1. Field of the Invention

The present invention generally relates to a distortion cancellation technique, and more particularly, to an apparatus and method capable of canceling non-linear distortion, such as second harmonic distortion in a picture carrier, when performing digital signal processing.

2. Background Information

Signal distortion can adversely affect the operation of an apparatus such as a television signal receiver. Such distortion may be attributable to various sources. For example, signal distortion may be attributable to the non-linear effects of certain analog amplifiers, and/or to the process of converting signals from an analog format to a digital format. Accordingly, in apparatuses such as television signal receivers that perform both analog and digital signal processing, signal distortion can be a significant problem.

When converting signals from an analog format to a digital format, signal distortion can be translated to troublesome frequencies as a result of heterodyning that occurs when the clock frequency of an analog-to-digital converter is less than the frequency of the input signal being converted. For example, the tuner of a television signal receiver may produce at its output a picture carrier having a frequency of 45.75 MHz and a sound carrier having a frequency of 41.25 MHz. The analog-to-digital converter in the signal path following the tuner may for example use a lower clock frequency, such as 25.1429 MHz, in order to satisfy certain design constraints of the receiver. In this example, because the clock frequency of the analog-to-digital converter is less than the frequencies of the input carrier signals being converted, heterodyning takes place and the picture carrier frequency at the output of the analog-to-digital converter is mapped to 4.5358 MHz, while the sound carrier frequency at the output of the analog-to-digital converter is mapped to 9.0358 MHz. In general, the output frequency of an analog-to-digital converter is equal to twice its clock frequency minus the frequency of the input signal being converted.

In the foregoing example, even if the linearity of the analog-to-digital converter is relatively good, some non-linear distortion may be present in its output signal. For example, it is noted that the second harmonic of the 4.5358 MHz picture carrier frequency is 9.0716 MHz, which is 35.8 kHz above the 9.0358 MHz sound carrier frequency. As a result, this 35.8 kHz frequency is present when performing audio processing and may thereby cause problems in an L-R audio signal including an in-band audio beat. Moreover, if the picture carrier frequency has an offset at the tuner output, the 35.8 kHz frequency can move to more sensitive frequencies in the audio spectrum. Even though the second harmonic may be −60 dB with respect to the picture carrier, this can translate to −40 dB with respect to the sound carrier. Accordingly, the acceptable distortion level in such a case may be relatively low.

Heretofore, the problem of dealing with distortion, such as the non-linear distortion produced by an analog-to-digital converter as described above, has not been adequately addressed. Accordingly, there is a need for an apparatus and method capable of canceling such distortion when performing digital signal processing. The present invention addresses these and/or other issues.

### SUMMARY OF THE INVENTION

In accordance with an aspect of the present invention, an apparatus capable of canceling non-linear distortion is disclosed. According to an exemplary embodiment, the apparatus comprises a digital signal source for providing a digital signal, and processing means for processing the digital signal to generate a digitally processed signal. The processing means includes distortion canceling means for canceling non-linear distortion from the digital signal.

In accordance with another aspect of the present invention, a method for canceling distortion is disclosed. According to an exemplary embodiment, the method comprises steps of receiving a digital signal, and processing the digital signal to generate a digitally processed signal. The processing step includes canceling non-linear distortion from the digital signal.

In accordance with yet another aspect of the present invention, a television signal receiver is disclosed. According to an exemplary embodiment, the television signal receiver comprises a digital signal source for providing a digital signal, and a processor operative to process the digital signal to generate a digitally processed signal. The processor includes distortion canceling circuitry for canceling non-linear distortion from the digital signal.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 is a block diagram of an apparatus according to an exemplary embodiment of the present invention;

FIG. 2 is a diagram providing further details of the IF processing block of FIG. 1 according to an exemplary embodiment of the present invention;

FIG. 3 is a diagram providing further details of the AGC and distortion canceling block of FIG. 2 according to an exemplary embodiment of the present invention; and

FIG. 4 is a flowchart illustrating steps according to an exemplary embodiment of the present invention.

The exemplifications set out herein illustrate preferred embodiments of the invention, and such exemplifications are not to be construed as limiting the scope of the invention in any manner.

### DESCRIPTION OF THE PREFERRED EMBODIMENTS

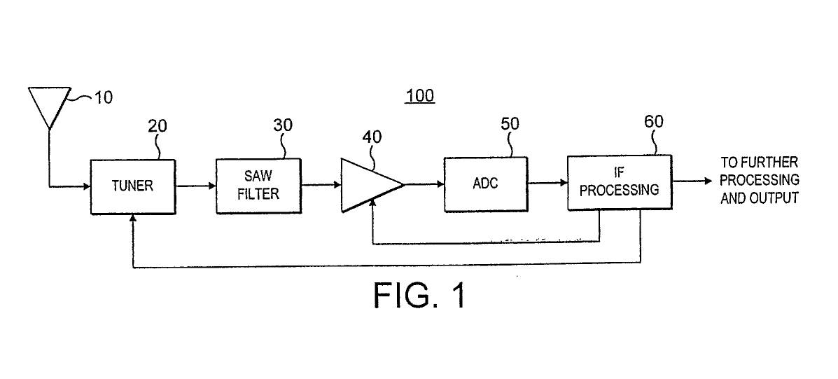

Referring now to the drawings, and more particularly to FIG. 1, a block diagram of an apparatus 100 according to an exemplary embodiment of the present invention is shown. As shown in FIG. 1, apparatus 100 comprises signal receiving means such as signal receiving element 10, tuning means such as tuner 20, filtering means such as surface acoustic wave (SAW) filter 30, amplifying means such as amplifier 40, analog-to-digital converting means such as analog-to-digital converter (ADC) 50, and intermediate frequency (IF) processing means such as IF processing block 60. Some of the foregoing elements of FIG. 1 may be embodied using integrated circuits (ICs), and some elements may for example be included on one or more ICs. For clarity of description, certain conventional elements associated with apparatus 100 such as certain control signals, power signals, clock signals and/or other elements may not be shown in FIG. 1. According to an exemplary embodiment, apparatus 100 is embodied as a television signal receiver, but may be embodied as another type of apparatus or device.

Signal receiving element 10 is operative to receive an RF signal from one or more signal sources such as terrestrial, cable, satellite, internet and/or other signal sources. According to an exemplary embodiment, signal receiving element 10 is embodied as an antenna, but may also be embodied as any type of signal receiving element such as an input terminal and/or other element.

Tuner 20 is operative to perform a signal tuning function. According to an exemplary embodiment, tuner 20 receives the RF input signal from signal receiving element 10, and performs the signal tuning function by filtering and frequency downconverting (i.e., single or multiple stage downconversion) the RF input signal to thereby generate an IF signal. The RF input signal and IF signal may include audio, video and/or data content, and may be of an analog modulation scheme (e.g., NTSC, PAL, SECAM, etc.) and/or a digital modulation scheme (e.g., ATSC, QAM, etc.). According to an exemplary embodiment, tuner 20 produces at its output a picture carrier having a carrier frequency of 45.75 MHz and a sound carrier having a carrier frequency of 41.25 MHz. Also according to an exemplary embodiment, tuner 20 receives an RF AGC signal from IF processing block 60 which enables an RF AGC function.

SAW filter 30 is operative to filter the IF signal provided from tuner 20 to thereby generate a filtered IF signal. According to an exemplary embodiment, SAW filter 30 includes one or more individual SAW filters which remove a substantial portion of the undesired, adjacent channel energy from the IF signal provided from tuner 20 to generate the filtered IF signal.

Amplifier 40 is operative to amplify the filtered IF signal provided from SAW filter 30 to thereby generate an amplified IF signal. According to an exemplary embodiment, amplifier 40 receives an IF AGC signal from IF processing block 60 which enables an IF AGC function. Due to the non-linear effects of amplifier 40, non-linear distortion may be present in the amplified IF signal produced by amplifier 40.

ADC 50 is operative to perform an analog-to-digital conversion function. According to an exemplary embodiment, ADC 50 converts the amplified IF signal provided from amplifier 40 from an analog format to a digital format to thereby generate a digital IF signal. According to this exemplary embodiment, the clock frequency of ADC 50 (and the digital processing after it) is 25.1429 MHz, although other clock frequencies may also be used. Because the clock frequency of ADC 50 is less than the frequencies of the amplified IF signal provided from amplifier 40, heterodyning takes place. As a result, the picture carrier frequency at the output of ADC 50 is mapped to 4.5358 MHz, while the sound carrier frequency at the output of ADC 50 is mapped to 9.0358 MHz. In general, the output frequency of ADC 50 is equal to twice its clock frequency minus the frequency of the input signal being converted. Because of the aforementioned heterodyning, there may be some additional non-linear distortion present in the digital IF signal produced from ADC 50. For example, the second harmonic of the 4.5358 MHz picture carrier frequency is 9.0716 MHz, which is 35.8 kHz above the 9.0358 MHz sound carrier frequency. As a result, this 35.8 kHz frequency may be present when performing audio processing and may thereby cause problems in an L-R audio signal including an in-band audio beat. Moreover, if the picture carrier frequency has an offset at the tuner output, the 35.8 kHz frequency can move to more sensitive frequencies in the audio spectrum. As will be described later herein, the present invention is capable of removing such non-linear distortion through digital signal processing.

IF processing block 60 is operative to perform various IF processing functions. According to an exemplary embodiment, IF processing block 60 processes the digital IF signal provided from ADC 50 to thereby generate various digitally processed signals. As will be described later herein, IF processing block 60 includes distortion canceling circuitry that cancels non-linear distortion from the digital IF signal provided from ADC 50. In this manner, the present invention advantageously avoids problems associated with non-linear distortion, such as the in-band audio beat in the L-R audio signal as previously described herein.

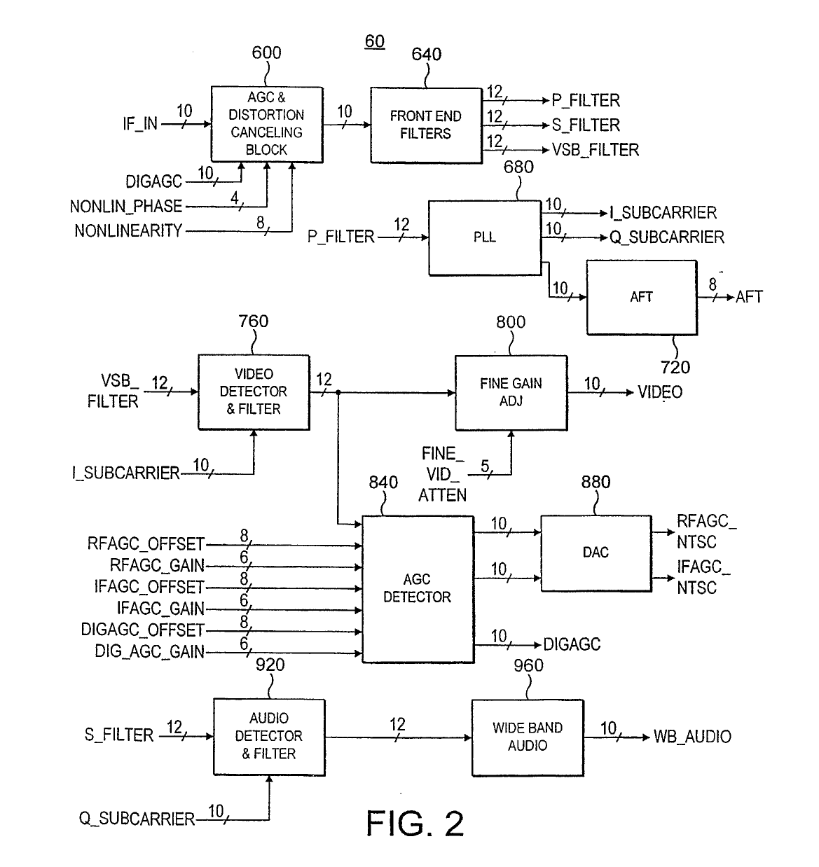

Referring now to FIG. 2, a diagram providing further details of IF processing block 60 of FIG. 1 according to an exemplary embodiment of the present invention is shown. As indicated in FIG. 2, digital IF processing block 60 comprises automatic gain control (AGC) and distortion canceling means such as AGC and distortion canceling block 600, front end filtering means such as front end filter 640, phase lock loop (PLL) means such as PLL 680, fine tuning means such as automatic fine tuning (AFT) block 720, video detecting and filtering means such as video detector and filter 760, fine gain adjusting means such as fine gain adjustment block 800, AGC detecting means such as AGC detector 840, digital-to-analog converting means such as digital-to-analog converter (DAC) 880, audio detecting and filtering means such as audio detector and filter 920, and wide band audio means such as wide band audio block 960. The foregoing elements of FIG. 2 may be embodied using ICs, and some elements may for example be included on one or more ICs. Although not expressly shown, the elements of FIG. 2 are clocked in accordance with a clock signal, which according to an exemplary embodiment has a frequency of 25.1429 MHz. Other clock frequencies may also be used according to the present invention. Also in FIG. 2, the number above each signal line represents the bit width of each signal according to an exemplary embodiment. The “*” symbol indicates that the signal is unsigned.

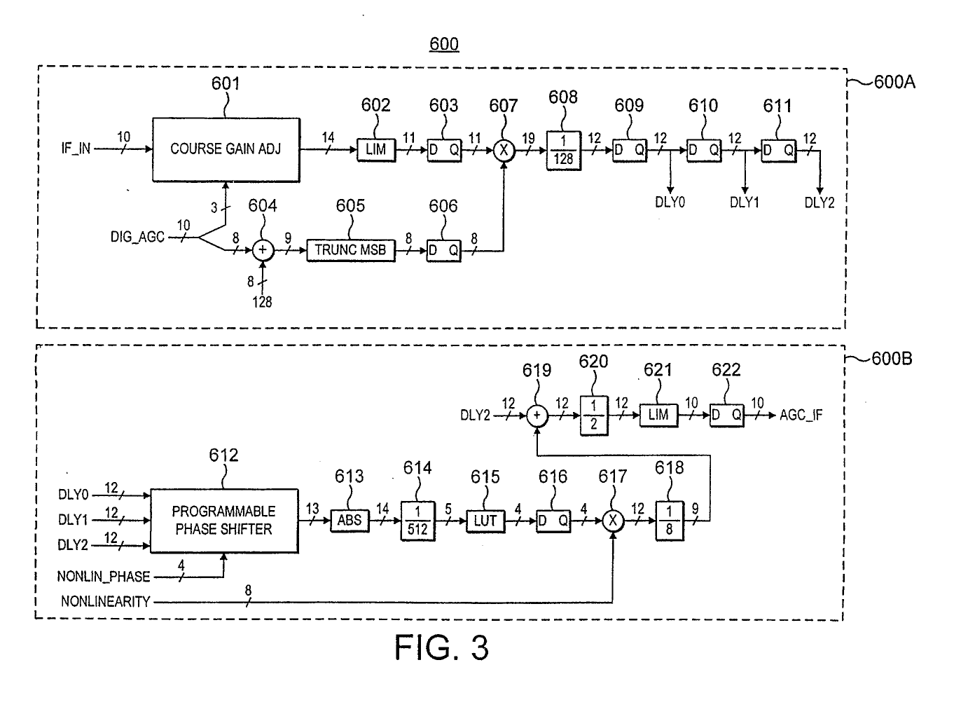

AGC and distortion canceling block 600 is operative to perform AGC and distortion canceling functions. According to an exemplary embodiment, AGC and distortion canceling block 600 receives and processes the 10-bit digital IF signal (IF_IN) provided from ADC 50 to thereby generate a 10-bit digitally processed IF signal. As indicated in FIG. 2, AGC and distortion canceling block 600 performs its functions responsive to certain control signals including a 10-bit DIGAGC signal, a 4-bit NONLIN_PHASE signal, and an 8-bit NONLINEARITY signal. Further details regarding these control signals and the operation of AGC and distortion canceling block 600 will be provided later herein with reference to FIG. 3.

Front end filters 640 are operative to perform front end filtering functions. According to an exemplary embodiment, front end filters 640 process the 10-bit digitally processed IF signal provided from AGC and distortion canceling block 600 to thereby generate three digitally filtered signals, namely, a P_FILTER signal, an S_FILTER signal, and a VSB_FILTER signal. As indicated in FIG. 2, each of these filtered signals is a 12-bit digital signal. The P_FILTER signal is a narrow bandpass filtered signal, centered on the picture carrier. The S_FILTER signal is a narrow bandpass filtered signal, centered on the sound carrier. The VSB_FILTER signal is a vestigial sideband signal having a specified vestigial slope in the vicinity of the picture carrier and approximately flat passband to beyond a chroma subcarrier frequency. In other words, the VSB_FILTER signal is a composite video signal having vestigial sideband filtering.

PLL 680 is operative to generate in-phase and quadrature picture subcarrier signals. According to an exemplary embodiment, PLL 680 generates a 10-bit in-phase picture subcarrier signal, I_SUBCARRIER, and a 10-bit quadrature picture subcarrier signal, Q_SUBCARRIER, responsive to the 12-bit P_FILTER signal provided from front end filters 640. In particular, the P_FILTER signal drives PLL 680 to enable generation of the sinusoidal I_SUBCARRIER and Q_SUBCARRIER signals used by other elements of IF processing block 60, as will be described later herein. Also according to an exemplary embodiment, PLL 680 is operative to generate a 19-bit frequency error signal that represents a detected frequency error in PLL 680.

AFT block 720 is operative to control an automatic fine tuning function. According to an exemplary embodiment, AFT block 720 generates an 8-bit AFT signal responsive to the 19-bit frequency error signal provided from PLL 680, and provides the 8-bit AFT signal to a processor (not shown in FIGS.) to thereby control the automatic fine tuning function.

Video detector and filter 760 is operative to perform video detection and filtering functions. According to an exemplary embodiment, video detector and filter 760 multiplies the 12-bit VSB_FILTER signal with the 12-bit I-SUBCARRIER signal and filters the resultant multiplied signal to remove sound and undesired adjacent channel energy and thereby generate a 12-bit filtered video signal.

Fine gain adjustment block 800 is operative to perform a fine gain adjustment function. According to an exemplary embodiment, fine gain adjustment block 800 performs the fine gain adjustment function responsive to a 5-bit FINE_VID_ATTEN signal provided via an inter-integrated circuit (IIC) bus to thereby generate a 10-bit VIDEO signal. The value of the FINE_VID_ATTEN signal may be selected by an application circuit designer as a matter of design choice and programmed into a non-volatile memory (not shown in FIGS.) of apparatus 100.

AGC detector 840 is operative to perform AGC detection functions. According to an exemplary embodiment, AGC detector 840 performs the AGC detection functions responsive to various RF and IF AGC signals including an 8-bit RFAGC_OFFSET signal, a 6-bit RFAGC_GAIN signal, an 8-bit IFAGC_OFFSET signal, a 6-bit IFAGC_GAIN signal, an 8-bit DIGAGC_OFFSET signal, and a 6-bit DIGAGC_GAIN signal. The aforementioned signals are provided to AGC detector 840 via an IIC bus, and are used to generate a 10-bit RFAGC signal, a 10-bit IFAGC signal, and a 10-bit DIGAGC signal that control the loop gain and offset (i.e., delay point) for RF and IF AGC functions. The values of the aforementioned signals may be selected by an application circuit designer as a matter of design choice and programmed into a non-volatile memory (not shown in FIGS.) of apparatus 100.

DAC 880 is operative to perform a digital-to-analog conversion function. According to an exemplary embodiment, DAC 880 converts the 10-bit RFAGC signal and the 10-bit IFAGC signal to an analog RFAGC_NTSC signal and an analog IFAGC_NTSC signal, respectively. The RFAGC_NTSC signal and the IFAGC_NTSC signal are provided to tuner 20 and amplifier 40, respectively, as shown in FIG. 1 to thereby provide RF and IF AGC functions. DAC 880 may for example be embodied as a binary rate multiplier.

Audio detector and filter 920 is operative to an audio detection and filtering function. According to an exemplary embodiment, audio detector and filter 920 multiplies the 12-bit S_FILTER signal with the 12-bit Q-SUBCARRIER signal and filters the resultant multiplied signal to thereby generate a 12-bit filtered audio signal representing a 4.5 MHz sound subcarrier.

Wide band audio block 960 is operative to generate a wide band audio signal. According to an exemplary embodiment, wide band audio block 960 generates a 16-bit wide band audio signal responsive to the 12-bit filtered audio signal provided from audio detector and filter 920.

Referring to FIG. 3, a diagram providing further details of AGC and distortion canceling block 600 of FIG. 2 according to an exemplary embodiment of the present invention is shown. As indicated in FIG. 3, AGC gain and distortion canceling block 600 comprises AGC means such as AGC circuit 600A and distortion canceling means such as distortion canceling circuit 600B. AGC circuit 600A of FIG. 3 comprises course gain adjusting means such as course gain adjustment block 601, limiting means such as limiter 602, first flip-flop means such as D-type flip-flop 603, adding means such as adder 604, truncating means such as truncator 605, second flip-flop means such as D-type flip-flop 606, first multiplying means such as multiplier 607, first dividing means such as divider 608, third flip-flop means such as D-type flip-flop 609, fourth flip-flop means such as D-type flip-flop 610, and fifth flip-flop means such as D-type flip-flop 611. Distortion canceling circuit 600B of FIG. 3 comprises programmable phase shifting means such as programmable phase shifter 612, absolute value means such as absolute value block 613, second dividing means such as divider 614, look up table (LUT) means such as LUT 615, sixth flip-flop means such as D-type flip-flop 616, second multiplying means such as multiplier 617, third dividing means such as divider 618, second adding means such as adder 619, fourth dividing means such as divider 620, second limiting means such as limiter 621, and seventh flip-flop means such as D-type flip-flop 622. Although not expressly shown, the elements of FIG. 3 are clocked in accordance with a clock signal, which according to an exemplary embodiment has a frequency of 25.1429 MHz. Other clock frequencies may also be used according to the present invention. Also in FIG. 3, the number above each signal line represents the bit width of each signal according to an exemplary embodiment. The symbol indicates that the signal is unsigned.

Course gain adjustment block 601 is operative to perform a course gain adjustment function. According to an exemplary embodiment, course gain adjustment block 601 receives and processes the 10-bit IF_IN signal provided from ADC 50 (see FIG. 1) responsive to the 3 most significant bits (MSBs) of the 10-bit DIG_AGC signal to thereby generate a 14-bit output signal. The value of the 10-bit DIG_AGC signal may be selected by an application circuit designer as a matter of design choice and programmed into a non-volatile memory (not shown in FIGS.) of apparatus 100. The 10-bit DIG_AGC signal is provided to AGC circuit 600A via an IIC bus. According to this exemplary embodiment, course gain adjustment block 601 generates the 14-bit output signal in accordance with Table 1 below, where “X” represents a “don't care” condition.

TABLE 1

| 3 MSBs of | |
|---|---|
| DIG_AGC Signal | Value of 14-bit Output Signal |
| 000 | X1 |
| 001 | X2 |
| 010 | X4 |
| 011 | X8 |
| 1XX | X16 |

Limiter 602 is operative to limit the 14-bit output signal provided from course adjustment block 601 to a predetermined range of values, which may be matter of design choice, to thereby generate an 11-bit output signal. D-type flip-flop 603 is operative to receive and output the 11-bit output signal provided from limiter 602 in accordance with the applicable clock signal.

Adder 604 is operative to add the 7 least significant bits (LSBs) of the 10-bit DIG_AGC signal to a value of 128 to thereby generate a 9-bit sum signal. Truncator 605 is operative to truncate the most significant bit from the 9-bit sum signal provided from adder 604 to thereby generate an 8-bit truncated signal. D-type flip-flop 606 is operative to receive and output the 8-bit truncated signal provided from truncator 605 in accordance with the applicable clock signal. Multiplier 607 is operative to multiply the 11-bit output signal provided from D-type flip-flop 603 by the 8-bit output signal provided from D-type flip-flop 606 to thereby generate a 19-bit multiplied signal.

Divider 608 is operative to divide the 19-bit multiplied signal provided from multiplier 607 by a value of 128 to thereby generate a 12-bit divided signal. D-type flip-flop 609 is operative to receive and output the 12-bit divided signal provided from divider 608 in accordance with the applicable clock signal. The 12-bit output signal provided from D-type flip-flop 609 is referred to herein as the DLY0 signal. D-type flip-flop 610 is operative to receive and output the 12-bit output signal (i.e., the DLY0 signal) provided from D-type flip-flop 609 in accordance with the applicable clock signal. The 12-bit output signal provided from D-type flip-flop 610 is referred to herein as the DLY1 signal. D-type flip-flop 611 is operative to receive and output the 12-bit output signal (i.e., the DLY1 signal) provided from D-type flip-flop 610 in accordance with the applicable clock signal. The 12-bit output signal provided from D-type flip-flop 611 is referred to herein as the DLY2 signal.

Programmable phase shifter 612 is operative to perform a programmable phase shifting function. According to an exemplary embodiment, programmable phase shifter 612 generates a 15-bit output signal responsive to the DLY0, DLY1, and DLY2 signals provided from AGC circuit 600A, and the 4-bit NONLIN_PHASE signal provided via an IIC bus. The value of the 4-bit NONLIN_PHASE signal may be selected by an application circuit designer as a matter of design choice and programmed into a non-volatile memory (not shown in FIGS.) of apparatus 100. According to this exemplary embodiment, programmable phase shifter 612 generates the 15-bit output signal in accordance with Table 2 below.

TABLE 2

| Value of NONLIN_PHASE Signal | Output Signal of 612 |
|---|---|
| 5 | 3DLY1 + 5DLY2 |
| 4 | 4DLY1 + 4DLY2 |
| 3 | 5DLY1 + 3DLY2 |
| 2 | 6DLY1 + 2DLY2 |
| 1 | 7DLY1 + DLY2 |
| 0 | 8DLY1 |
| −1 | DLY0 + 7DLY1 |
| −2 | 2DLY0 + 6DLY1 |
| −3 | 3DLY0 + 5DLY1 |
| −4 | 4DLY0 + 4DLY1 |
| −5 | 5DLY0 + 3DLY1 |

As indicated in Table 2, the value of the NONLIN_PHASE signal is used to control the weighting of the DLY0, DLY1, and DLY2 signals in the 15-bit output signal of programmable phase shifter 612. According to this exemplary embodiment, the 15-bit output signal of programmable phase shifter 612 provides phase shifts in steps corresponding to ⅛^{th} of a clock cycle (i.e., 25.1429 MHz). The eleven steps of programmable phase shifter 612 correspond to a range of plus or minus 81 degrees in approximately 16 degree steps.

Absolute value block 613 is operative to take the absolute value of the 15-bit output signal provided from programmable phase shifter 612 to thereby generate a 14-bit absolute value signal. Divider 614 is operative to divide the 14-bit absolute value signal provided from absolute value block 613 by a value of 512 to thereby generate a 5-bit divided signal. LUT 615 is operative to perform a look up table function and thereby generate a 4-bit output signal that is proportional to the square of the 15-bit output signal of programmable phase shifter 612. D-type flip-flop 616 is operative to receive and output the 4-bit output signal provided from LUT 615 in accordance with the applicable clock signal. The 4-bit output signal of D-type flip-flop 616 represents artificially generated second harmonic distortion of the picture carrier, and exactly tracks the frequency and amplitude of the IF_IN signal. According to the exemplary embodiment described above, absolute value block 613, divider 614, LUT 615, and D-type flip-flop 616 perform a signal squaring function in order to generate an estimate of second harmonic distortion. It is noted, however, that these elements may be modified to generate an estimate of other harmonics (e.g., 3^{rd}, 4^{th}, etc.). For example, absolute value block 613, divider 614, LUT 615, and D-type flip-flop 616 may be modified to perform a signal cubing function in order to generate an estimate of third harmonic distortion, and so on.

Multiplier 617 is operative to multiply the 4-bit output signal provided from D-type flip-flop 616 by the 8-bit NONLINEARITY signal to thereby generate a 12-bit multiplied signal. The 8-bit NONLINEARITY signal is provided via an IIC bus. According to an exemplary embodiment, the gain and polarity of the artificially generated second harmonic distortion represented by the 4-bit output signal of D-type flip-flop 616 is controlled by the 8-bit NONLINEARITY signal. The value of the 8-bit NONLINEARITY signal may be selected by an application circuit designer as a matter of design choice and programmed into a non-volatile memory (not shown in FIGS.) of apparatus 100. Divider 618 is operative to divide the 12-bit multiplied signal provided from multiplier 617 by a value of 8 to thereby generate a 9-bit divided signal that represents an inverse of the artificially generated second harmonic (or other desired harmonic) distortion.

Adder 619 is operative to add the 9-bit divided signal provided from divider 618 to the 12-bit DLY2 signal provided from D-type flip-flop 611 to thereby generate a 13-bit sum signal. This operation by adder 619 effectively cancels the second harmonic (or other desired harmonic) distortion from the 12-bit DLY2 signal, which is a time-aligned version of the IF_IN signal. In practice, the values of the aforementioned NONLINEARITY and NONLIN_PHASE signals are selected to null out the desired harmonic (e.g., second harmonic) distortion for a specified alignment condition.

Divider 620 is operative to divide the 13-bit sum signal provided from adder 619 by a value of 2 to thereby generate a 12-bit divided signal. Limiter 621 is operative to limit the 12-bit divided signal provided from divider 620 to a predetermined range of values, which may be matter of design choice, to thereby generate a 10-bit output signal. D-type flip-flop 622 is operative to receive and output the 10-bit output signal provided from limiter 621 in accordance with the applicable clock signal. As indicated in FIG. 3, the output signal of D-type flip-flop 622 is the 10-bit, distortion cancelled AGC_IF signal provided to front end filters 640 in FIG. 2.

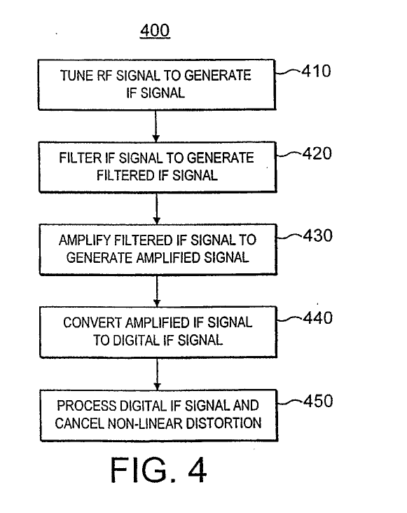

To facilitate a better understanding of the present invention, an example will now be provided. Referring now to FIG. 4, a flowchart 400 illustrating steps according to an exemplary embodiment of the present invention is shown. For purposes of example and explanation, the steps of FIG. 4 will be described with reference to the elements of apparatus 100 as previously described herein. The steps of FIG. 4 are merely exemplary, and are not intended to limit the present invention in any manner.

At step 410, apparatus 100 tunes an RF signal to thereby generate an IF signal. According to an exemplary embodiment, tuner 20 receives the RF signal from signal receiving element 10, and performs the signal tuning function by filtering and frequency downconverting (i.e., single or multiple stage downconversion) the RF signal to thereby generate the IF signal at step 410. As previously indicated herein, the RF signal and IF signal may include audio, video and/or data content, and may be of an analog modulation scheme (e.g., NTSC, PAL, SECAM, etc.) and/or a digital modulation scheme (e.g., ATSC, QAM, etc.). According to an exemplary embodiment, tuner 20 produces at its output a picture carrier having a center frequency of 45.75 MHz and a sound carrier having a center frequency of 41.25 MHz.

At step 420, apparatus 100 filters the IF signal to thereby generate a filtered IF signal. According to an exemplary embodiment, SAW filter 30 uses its one or more individual SAW filters to remove a substantial portion of the undesired, adjacent channel energy from the IF signal provided from tuner 20 to thereby generate the filtered IF signal at step 420.

At step 430, apparatus 100 amplifies the filtered IF signal to thereby generate an amplified IF signal. According to an exemplary embodiment, amplifier 40 amplifies the filtered IF signal provided from SAW filter 30 to thereby generate the amplified IF signal at step 430. As previously indicated herein, non-linear effects of amplifier 40 may cause non-linear distortion to be present in the amplified IF signal generated at step 430.

At step 440, apparatus 100 converts the amplified IF signal to a digital IF signal. According to an exemplary embodiment, ADC 50 converts the amplified IF signal provided from amplifier 40 from an analog format to a digital format to thereby generate the digital IF signal at step 440. According to this exemplary embodiment, the clock frequency of ADC 50 (and the digital processing after it) is 25.1429 MHz, although other clock frequencies may also be used. Because the clock frequency of ADC 50 is less than the frequencies of the amplified IF signal provided from amplifier 40, heterodyning takes place. As a result, the picture carrier frequency at the output of ADC 50 is mapped to 4.5358 MHz, while the sound carrier frequency at the output of ADC 50 is mapped to 9.0358 MHz. Because of the heterodyning, there may be some additional non-linear distortion present in the digital IF signal produced from ADC 50 at step 440. For example, the second harmonic of the 4.5358 MHz picture carrier frequency is 9.0716 MHz, which is 35.8 kHz above the 9.0358 MHz sound carrier frequency. As a result, this 35.8 kHz frequency may be present when performing audio processing and may thereby cause problems in an L-R audio signal including an in-band audio beat. Moreover, if the picture carrier frequency has an offset at the tuner output, the 35.8 kHz frequency can move to more sensitive frequencies in the audio spectrum.

At step 450, apparatus 100 processes the digital IF signal and cancels non-linear distortion from the digital IF signal. According to an exemplary embodiment, IF processing block 60 processes the digital IF signal provided from ADC 50 using the distortion canceling circuit 600B to thereby remove non-linear distortion at step 450. As previously described herein, distortion canceling circuit 600B artificially generates an inverse estimate of the desired harmonic to be removed, and adds this inverse estimate to a time-aligned version of digital IF signal to thereby cancel non-linear distortion. In the aforementioned manner, the present invention advantageously avoids problems associated with non-linear distortion, such as the in-band audio beat in the L-R audio signal as previously described herein.

As described herein, the present invention provides an apparatus and method capable of canceling non-linear distortion, such as second harmonic distortion in a picture carrier, when performing digital signal processing. The present invention may be applicable to various apparatuses, either with or without an integrated display device. Accordingly, the phrase “television signal receiver” as used herein may refer to systems or apparatuses including, but not limited to, television sets, computers or monitors that include an integrated display device, and systems or apparatuses such as set-top boxes, video cassette recorders (VCRs), digital versatile disk (DVD) players, video game boxes, personal video recorders (PVRs), computers or other apparatuses that may not include an integrated display device.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

1. An apparatus, comprising:
a digital signal source for providing a digital signal;
processing means for processing said digital signal to generate a digitally processed signal; and
wherein said processing means includes distortion canceling means (600B) for canceling non-linear distortion from said digital signal.

2. The apparatus of claim 1, wherein said non-linear distortion includes second-harmonic distortion of a picture carrier.

3. The apparatus of claim 1, wherein said digital signal source includes analog-to-digital converting means for converting an analog signal to said digital signal.

4. The apparatus of claim 3, further comprising:
tuning means for tuning an RF signal to generate an IF signal;
filtering means for filtering said IF signal to generate a filtered IF signal; and
amplifying means for amplifying said filtered IF signal to generate said analog signal and providing said analog signal to said analog-to-digital converting means.

5. The apparatus of claim 4, wherein said non-linear distortion is produced from at least one of said analog-to-digital converting means and said amplifying means.

6. The apparatus of claim 1, wherein said distortion canceling means includes programmable phase shifting means for performing a phase shifting function to enable generation of said digitally processed signal.

7. A method for canceling non-linear distortion, comprising steps of:
receiving a digital signal;
processing said digital signal to generate a digitally processed signal; and
wherein said processing step includes canceling non-linear distortion from said digital signal.

8. The method of claim 7, wherein said non-linear distortion includes second-harmonic distortion of a picture carrier.

9. The method of claim 7, further comprising a step of converting an analog signal to said digital signal.

10. The method of claim 9, further comprising steps of:
tuning an RF signal to generate an IF signal;
filtering said IF signal to generate a filtered IF signal; and
amplifying said filtered IF signal to generate said analog signal.

11. The method of claim 10, wherein said non-linear distortion is produced from at least one of said converting step and said amplifying step.

12. The method of claim 7, wherein said step of canceling said non-linear distortion from said digital signal includes performing a phase shifting function to enable generation of said digitally processed signal.

13. A television signal receiver, comprising:
a digital signal source for providing a digital signal;
a processor operative to process said digital signal to generate a digitally processed signal; and
wherein said processor includes distortion canceling circuitry for canceling non-linear distortion from said digital signal.

14. The television signal receiver of claim 13, wherein said non-linear distortion includes second-harmonic distortion of a picture carrier.

15. The television signal receiver of claim 13, wherein said digital signal source includes an analog-to-digital converter operative to convert an analog signal to said digital signal.

16. The television signal receiver of claim 15, further comprising:
a tuner operative to tune an RF signal to generate an IF signal;
a filter operative to filter said IF signal to generate a filtered IF signal; and
an amplifier operative to amplify said filtered IF signal to generate said analog signal and provide said analog signal to said analog-to-digital converter.

17. The television signal receiver of claim 16, wherein said non-linear distortion is produced from at least one of said analog-to-digital converter and said amplifier.

18. The television signal receiver of claim 13, wherein said distortion canceling circuitry includes a programmable phase shifter operative to perform a phase shifting function to enable generation of said digitally processed signal.

19. A method for canceling distortion, comprising:
generating a first digital signal representing an amount of inverse distortion; and
using said first digital signal to cancel distortion from a second digital signal.

20. The method of claim 19, wherein said generating step includes:
generating a phase shifted digital signal responsive to said second digital signal; and
using said phase shifted digital signal to generate said first digital signal.
